(19) United States
(12) Patent Application Publication
(10) Pub. No.: US 2024/0373543 A1
(43) Pub. Date: Nov. 7, 2024

(54) PRINTED CIRCUIT BOARD ASSEMBLIES WITH ALUMINUM PCB SUBSTRATES IN HOME APPLIANCES AND METHODS THEREOF

(71) Applicant: GUANGZHOU ON-BRIGHT ELECTRONICS CO., LTD, Guangzhou (CN)

(72) Inventors: XIAOKUI CHEN, Guangzhou (CN); ZHILIANG CHEN, Shanghai (CN); YUNHAO FU, Guangzhou (CN); JIAQIANG HUANG, Guangzhou (CN)

(21) Appl. No.: 18/375,266

(22) Filed: Sep. 29, 2023

(30) Foreign Application Priority Data
May 6, 2023 (CN) 2023105075770
May 6, 2023 (CN) 2023210774304

(51) Int. Cl. H05K 1/02; H05K 3/00

(52) U.S. Cl. CPC H05K 1/0209; H05K 1/0298; H05K 3/0061; H05K 2201/0355

(57) ABSTRACT

Printed circuit board assembly and method thereof. For example, a printed circuit board assembly includes: an aluminum substrate; an insulating layer on the aluminum substrate; a conductive layer on the insulating layer; and one or more surface-mount electronic devices on the aluminum substrate through the conductive layer and the insulating layer; wherein: the one or more surface-mount electronic devices include at least one converted surface-mount electronic device, the one converted surface-mount electronic device being converted from a through-hole electronic device; and the one converted surface-mount electronic device is on the aluminum substrate through the conductive layer and the insulating layer; wherein the aluminum substrate is made of aluminum.

### 1. CROSS-REFERENCES TO RELATED APPLICATIONS

This application claims priority to Chinese Patent Application No. 2023105075770, filed on May 6, 2023, and Chinese Patent Application No. 2023210774304, filed on May 6, 2023, both of which are incorporated by reference herein for all purposes.

### 2. FIELD OF THE DISCLOSURE

Certain embodiments of the present disclosure are directed to printed circuit board assemblies. More particularly, some embodiments of the disclosure provide printed circuit board assemblies with aluminum PCB substrates and methods thereof. Merely by way of example, some embodiments of the disclosure have been applied to home appliances. But it would be recognized that the disclosure has a much broader range of applicability.

### 3. BACKGROUND OF THE DISCLOSURE

In a variety of home appliances, a printed circuit board assembly (PCBA) often serves as an important underlying hardware. The PCBA usually includes a printed circuit board (PCB) and one or more chips that are on the printed circuit board. The one or more chips contain one or more integrated circuits. It is usually important to efficiently and effectively make the PCBA.

Conventionally, a printed circuit board (PCB) often includes a PCB substrate. For example, the PCB substrate is made of epoxy resin. As an example, the PCB substrate is made of fiberglass. On the PCB substrate, one or more chips with one or more integrated circuits are usually installed to realize one or more hardware functions in cooperation with one or more external electronic devices. Often, the making of the one or more integrated circuits of the one or more chips and the assembling of the PCBA are performed by different manufacturers each with their own processes. Hence, it is usually difficult to optimize the entire production process from the making of the one or more integrated circuits to the assembling of the PCBA.

FIG. 1A and FIG. 1B are simplified diagrams showing a conventional printed circuit board assembly (PCBA) with an epoxy resin PCB substrate as part of a home appliance. The PCBA 100 includes an epoxy resin PCB substrate 110 that is made of epoxy resin. The epoxy resin PCB substrate 110 has an inadequate heat dissipation performance. For example, the home appliance is an induction cooker (e.g., an induction cooktop). As an example, the home appliance is an electric water heater.

As shown in FIG. 1A, the PCBA 100 also includes one or more power electronic devices 120, one or more heat sinks 122, and one or more other electronic devices 130 that are not power electronic devices. The one or more power electronic devices 120, the one or more heat sinks 122, and the one or more other electronic devices 130 are assembled onto the epoxy resin PCB substrate 110. The one or more power electronic devices 120 generate significant heat during operation due to one or more large currents, and thus use the one or more heat sinks 122 to improve heat dissipation. The one or more heat sinks 122 are made of copper and/or aluminum and are therefore costly.

As shown in FIG. 1B, the PCBA 100 also includes one or more through-hole electronic devices 140) and one or more surface-mount electronic devices 150. The one or more through-hole electronic devices 140 and the one or more surface-mount electronic devices 150 use at least two different assembly processes in the production of the PCBA 100, thus making the production process of the PCBA more complex. One of the two different assembly processes utilizes the through-hole technology, and the other of the two different assembly processes utilizes the surface-mount technology.

In some examples, the one or more through-hole electronic devices 140 as shown in FIG. 1B include some of the one or more power electronic devices 120 as shown in FIG. 1A and/or some of the one or more other electronic devices 130 that are not power electronic devices as shown in FIG. 1A. For example, some of the one or more through-hole electronic devices 140 as shown in FIG. 1B are in contact with some of the one or more heat sinks 122 as shown in FIG. 1A. In certain examples, the one or more surface-mount electronic devices 150 as shown in FIG. 1B include some of the one or more power electronic devices 120 as shown in FIG. 1A and/or some of the one or more other electronic devices 130 that are not power electronic devices as shown in FIG. 1A. For example, some of the one or more surface-mount electronic devices 150 as shown in FIG. 1B are in contact with some of the one or more heat sinks 122 as shown in FIG. 1A.

FIG. 2 is a simplified diagram showing a conventional method for making the printed circuit board assembly (PCBA) 100 used in a home appliance as shown in FIG. 1A and FIG. 1B. The method 200 includes processes 210, 220, 230, 240, and 250. For example, the home appliance is an induction cooker (e.g., an induction cooktop). As an example, the home appliance is an electric water heater.

At the process 210, the one or more surface-mount electronic devices 150 are placed onto the epoxy resin PCB substrate 110 by one or more machines with surface mount technology. At the process 220, reflow soldering is performed to the one or more surface-mount electronic devices 150. At the process 230, the one or more through-hole electronic devices 140 are placed onto the epoxy resin PCB substrate 110 manually by one or more human operators. At the process 240, wave soldering is performed to the one or more through-hole electronic devices 140. At the process 250, the one or more heat sinks 122 are installed onto the epoxy resin PCB substrate 110 for the one or more power electronic devices 120 manually by one or more human operators.

The processes 210 and 220 are performed for the one or more surface-mount electronic devices 150, the processes 230 and 240 are performed for the one or more through-hole electronic devices 140, and the process 250 is performed for the one or more power electronic devices 120. As shown in FIG. 2, the method 200 involves switching between machine operation and manual operation, and such switching often lengthens the production process of the PCBA 100. Also, the manual operation is usually a bottleneck that restricts the production efficiency and also increases the defect rate.

FIG. 3 is a simplified diagram showing installation of a heat sink for an insulated-gate bipolar transistor according to the process 250 of the method 200 as shown in FIG. 2. An insulated-gate bipolar transistor 340 is a through-hole electronic device and is also a power electronic device. Before the installation of a heat sink 322, the insulated-gate bipolar transistor 340) is installed onto an epoxy resin PCB substrate 310 as a through-hole electronic device at the processes 230 and 240. Additionally, fastening screws 390 and 392 and thermally conductive silicone 380 are provided. During the installation of the heat sink 322 at the process 250, the thermally conductive silicone 380 is manually applied between the insulated-gate bipolar transistor 340 and the heat sink 322, the heat sink 322 is locked to the insulated-gate bipolar transistor 340 through the thermally conductive silicone 380 by the fastening screw 392, and the heat sink 322 is also locked to the epoxy resin PCB substrate 310 by the fastening screw 390.

FIG. 4 is a simplified diagram showing a conventional printed circuit board assembly (PCBA) with an epoxy resin PCB substrate as part of an induction cooker (e.g., an induction cooktop). The PCBA 400 includes an epoxy resin PCB substrate. For example, the PCBA 400 also includes one or more power electronic devices, one or more heat sinks, and one or more other electronic devices that are not power electronic devices. As an example, the PCBA 400 also includes one or more through-hole electronic devices and one or more surface-mount electronic devices. In some examples, the one or more through-hole electronic devices include some of the one or more power electronic devices and/or some of the one or more other electronic devices that are not power electronic devices. For example, some of the one or more through-hole electronic devices are in contact with some of the one or more heat sinks. In certain examples, the one or more surface-mount electronic devices include some of the one or more power electronic devices and/or some of the one or more other electronic devices that are not power electronic devices. For example, some of the one or more surface-mount electronic devices are in contact with some of the one or more heat sinks. As shown in FIG. 4, the PCBA 400 is an example of the PCBA 100 as shown in FIG. 1A and FIG. 1B.

FIG. 5 and FIG. 6 are simplified diagrams showing certain components of a conventional induction cooker (e.g., an induction cooktop) that includes a conventional printed circuit board assembly (PCBA). The induction cooker 500 includes a coil 510, a fan 520, and a printed circuit board assembly (PCBA) 530. For example, the coil 510 is used to generate a magnetic field. As an example, the fan 520 is used for cooling. For example, the PCBA 530 includes an epoxy resin PCB substrate.

FIG. 7A and FIG. 7B are simplified diagrams showing the printed circuit board assembly (PCBA) 530 with an epoxy resin PCB substrate as part of the conventional induction cooker 500 as shown in FIG. 5 and FIG. 6. FIG. 7A shows a top view of the PCBA 530, and FIG. 7B shows a bottom view of the PCBA 530. The PCBA 530 includes an epoxy resin PCB substrate that is made of epoxy resin. One or more through-hole electronic devices are placed on a top surface of the epoxy resin PCB substrate, and the one or more through-hole electronic devices are soldered, directly or indirectly, to a bottom surface of the epoxy resin PCB substrate. For example, the PCBA 530 is the PCBA 100 as shown in FIG. 1A and FIG. 1B. As an example, the PCBA 530 is the PCBA 400 as shown in FIG. 4.

FIG. 8 is a simplified diagram showing a conventional printed circuit board assembly (PCBA). In certain examples, FIG. 8 shows a section view of the printed circuit board assembly (PCBA) 800. The printed circuit board assembly (PCBA) 800 includes a printed circuit board (PCB) 802 and one or more electronic devices 804. For example, the PCBA 800 is the PCBA 100 as shown in FIG. 1A and FIG. 1B. As an example, the PCBA 800 is the PCBA 400 as shown in FIG. 4. For example, the PCBA 800 is the PCBA 530 as shown in FIG. 7A and FIG. 7B. In some examples, the PCBA 800 is part of a home appliance. For example, the PCBA 800 is part of an induction cooker (e.g., an induction cooktop). As an example, the PCBA 800 is part of an electric water heater.

The PCB 802 includes a PCB substrate 810 that is made of one or more insulating materials. For example, the PCB substrate 810 is made of epoxy resin. As an example, the PCB substrate 810 is made of fiberglass. The PCB substrate 810 includes a top surface 812 and a bottom surface 814. Additionally, the PCBA 800 also includes a conductive layer 820. For example, the conductive layer 820 is made of copper. As an example, the conductive layer 820 includes one or more copper foils. The conductive layer 820 includes a top surface 822 and a bottom surface 824. The top surface 822 of the conductive layer 820 is, directly or indirectly, in contact with the bottom surface 814 of the PCB substrate 810.

The one or more electronic devices 804 includes a through-hole electronic device 850. The through-hole electronic device 850 includes pins 852 and 854. As shown in FIG. 8, the through-hole electronic device 850 is placed on the top surface 812 of the PCB substrate 810. Additionally, the pin 852 of the through-hole electronic device 850 extends through a hole 882 in the PCB 802, and the pin 852 is attached to the bottom surface 824 of the conductive layer 820 through a solder block 892. Moreover, the pin 854 of the through-hole electronic device 850 extends through a hole 884 in the PCB 802, and the pin 854 is attached to the bottom surface 824 of the conductive layer 820 through a solder block 894.

Hence it is highly desirable to improve the technique for making printed circuit board assemblies.

### 4. BRIEF SUMMARY OF THE DISCLOSURE

Certain embodiments of the present disclosure are directed to printed circuit board assemblies. More particularly, some embodiments of the disclosure provide printed circuit board assemblies with aluminum PCB substrates and methods thereof. Merely by way of example, some embodiments of the disclosure have been applied to home appliances. But it would be recognized that the disclosure has a much broader range of applicability.

According to certain embodiments, a printed circuit board assembly includes: an aluminum substrate: an insulating layer on the aluminum substrate: a conductive layer on the insulating layer; and one or more surface-mount electronic devices on the aluminum substrate through the conductive layer and the insulating layer: wherein: the one or more surface-mount electronic devices include at least one converted surface-mount electronic device, the one converted surface-mount electronic device being converted from a through-hole electronic device; and the one converted surface-mount electronic device is on the aluminum substrate through the conductive layer and the insulating layer: wherein the aluminum substrate is made of aluminum.

According to some embodiments, a printed circuit board assembly of a home appliance includes: an aluminum substrate including a first substrate surface and a second substrate surface, the first substrate surface and the second substrate surface being opposite to each other: one or more converted surface-mount electronic devices on the first substrate surface of the aluminum substrate, the one or more converted surface-mount electronic devices being converted from one or more first through-hole electronic devices; and one or more additional surface-mount electronic devices on the first substrate surface of the aluminum substrate: wherein the aluminum substrate is made of aluminum.

According to certain embodiments, an induction cooker includes: a printed circuit board assembly; wherein the printed circuit board assembly includes: an aluminum substrate; an insulating layer on the aluminum substrate; a conductive layer on the insulating layer; and one or more surface-mount electronic devices on the aluminum substrate through the conductive layer and the insulating layer; wherein: the one or more surface-mount electronic devices include at least one converted surface-mount electronic device, the one converted surface-mount electronic device being converted from a through-hole electronic device; and the one converted surface-mount electronic device is on the aluminum substrate through the conductive layer and the insulating layer; wherein the aluminum substrate is made of aluminum.

According to some embodiments, an induction cooker includes: a printed circuit board assembly; wherein the printed circuit board assembly includes: an aluminum substrate including a first substrate surface and a second substrate surface, the first substrate surface and the second substrate surface being opposite to each other; one or more converted surface-mount electronic devices on the first substrate surface of the aluminum substrate, the one or more converted surface-mount electronic devices being converted from one or more first through-hole electronic devices; and one or more additional surface-mount electronic devices on the first substrate surface of the aluminum substrate; wherein the aluminum substrate is made of aluminum.

According to certain embodiments, a method for making a printed circuit board assembly (PCBA) of a home appliance includes: changing one or more through-hole electronic devices to one or more converted surface-mount electronic devices; placing the one or more converted surface-mount electronic devices and one or more additional surface-mount electronic devices onto an aluminum PCB substrate by one or more machines with surface mount technology; and performing reflow soldering to the one or more converted surface-mount electronic devices and the one or more additional surface-mount electronic devices; wherein the aluminum PCB substrate is made of aluminum.

Depending upon embodiment, one or more benefits may be achieved. These benefits and various additional objects, features and advantages of the present disclosure can be fully appreciated with reference to the detailed description and accompanying drawings that follow.

### 5. BRIEF DESCRIPTION OF THE DRAWINGS

FIG. 1A and FIG. 1B are simplified diagrams showing a conventional printed circuit board assembly (PCBA) with an epoxy resin PCB substrate as part of a home appliance.

FIG. 2 is a simplified diagram showing a conventional method for making the printed circuit board assembly (PCBA) used in a home appliance as shown in FIG. 1A and FIG. 1B.

FIG. 3 is a simplified diagram showing installation of a heat sink for an insulated-gate bipolar transistor according to a process of the conventional method as shown in FIG. 2.

FIG. 4 is a simplified diagram showing a conventional printed circuit board assembly (PCBA) with an epoxy resin PCB substrate as part of an induction cooker (e.g., an induction cooktop).

FIG. 5 and FIG. 6 are simplified diagrams showing certain components of a conventional induction cooker (e.g., an induction cooktop) that includes a conventional printed circuit board assembly (PCBA).

FIG. 7A and FIG. 7B are simplified diagrams showing the printed circuit board assembly (PCBA) with an epoxy resin PCB substrate as part of the conventional induction cooker as shown in FIG. 5 and FIG. 6.

FIG. 8 is a simplified diagram showing a conventional printed circuit board assembly (PCBA).

FIG. 9 is a simplified diagram showing a method for making a printed circuit board assembly (PCBA) with an aluminum PCB substrate used in a home appliance according to certain embodiments of the present disclosure.

FIG. 10A and FIG. 10B are simplified diagrams showing a process for changing an insulated-gate bipolar transistor from being a through-hole electronic device to being a converted surface-mount electronic device as part of the method for making a printed circuit board assembly (PCBA) as shown in FIG. 9 according to some embodiments of the present disclosure.

FIG. 11A and FIG. 11B are simplified diagrams showing a process for changing an inductive winding from being a through-hole electronic device to being a converted surface-mount electronic device as part of the method for making a printed circuit board assembly (PCBA) as shown in FIG. 9 according to certain embodiments of the present disclosure.

FIG. 12A and FIG. 12B are simplified diagrams showing a printed circuit board assembly (PCBA) with an aluminum PCB substrate that has been assembled by the method as shown in FIG. 9 as part of a home appliance according to some embodiments of the present disclosure.

FIG. 13 is a simplified diagram showing a printed circuit board assembly (PCBA) with an aluminum PCB substrate that has been assembled by the method as shown in FIG. 9 as part of an induction cooker (e.g., an induction cooktop) according to certain embodiments of the present disclosure.

FIG. 14 is a simplified diagram showing certain components of an induction cooker that includes a printed circuit board assembly (PCBA) with an aluminum PCB substrate according to certain embodiments of the present disclosure.

FIG. 15A and FIG. 15B are simplified diagrams showing the printed circuit board assembly (PCBA) as part of the induction cooker as shown in FIG. 14 according to some embodiments of the present disclosure.

FIG. 16 is a simplified diagram showing the printed circuit board assembly (PCBA) as part of the induction cooker as shown in FIG. 14 according to certain embodiments of the present disclosure.

FIG. 17 is a simplified diagram showing the printed circuit board assembly (PCBA) as part of the induction cooker as shown in FIG. 14 according to certain embodiments of the present disclosure.

FIG. 18 is a simplified diagram showing a printed circuit board assembly (PCBA) with an aluminum PCB substrate according to some embodiments of the present disclosure.

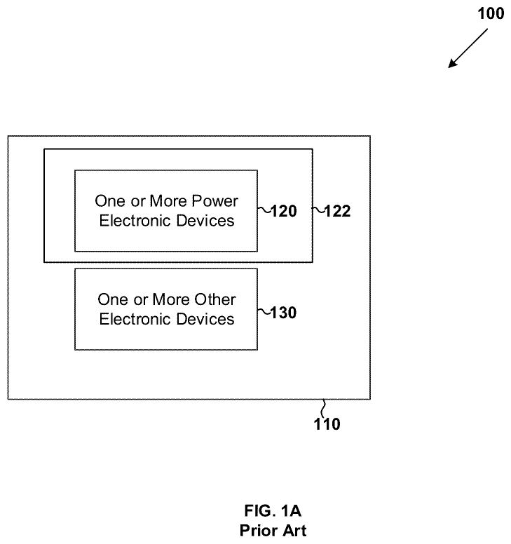

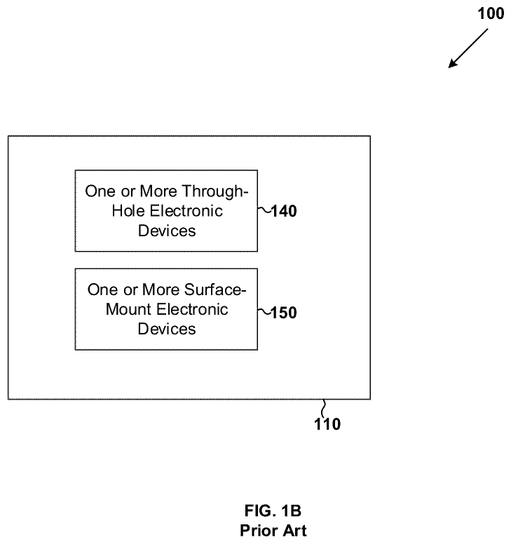

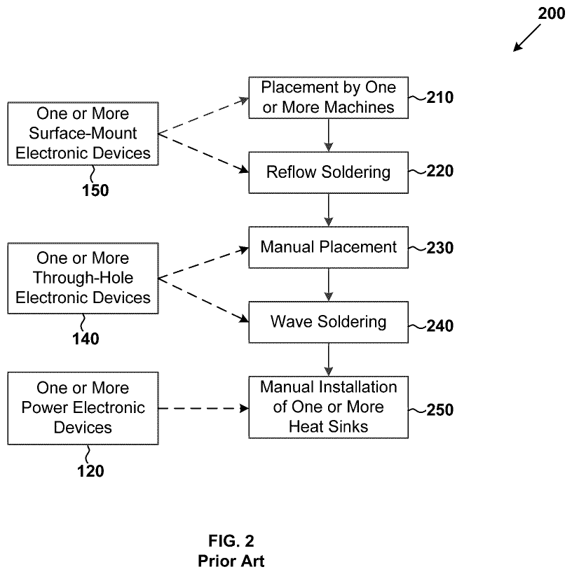

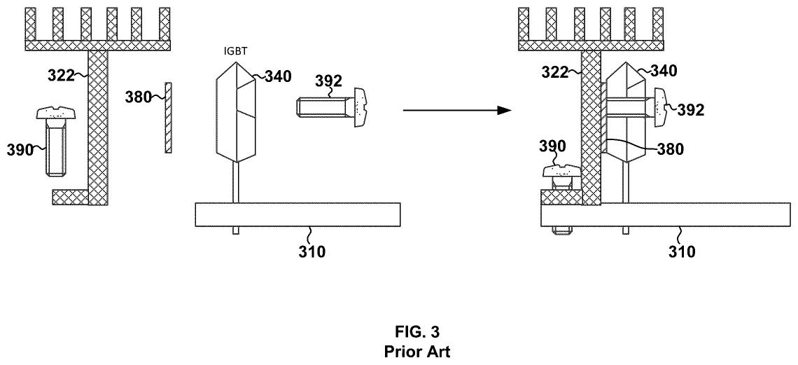

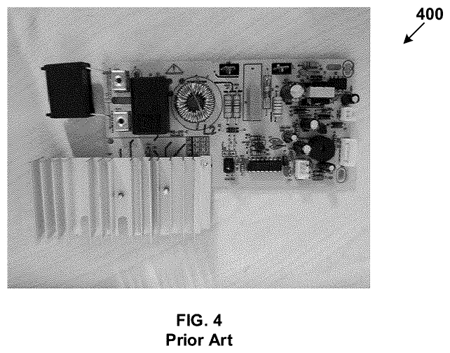

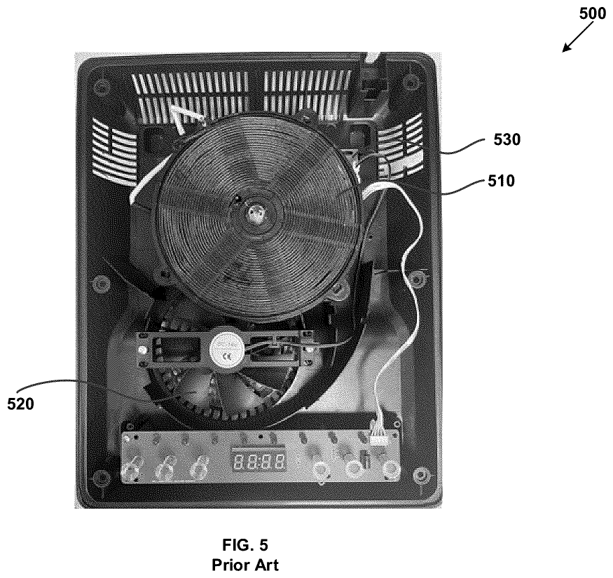

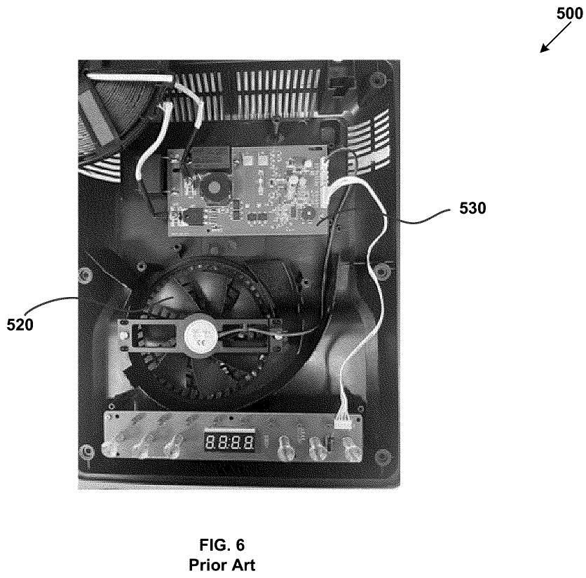

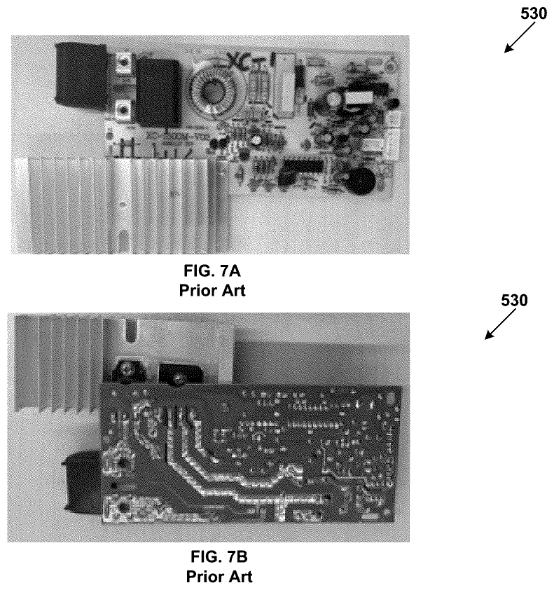

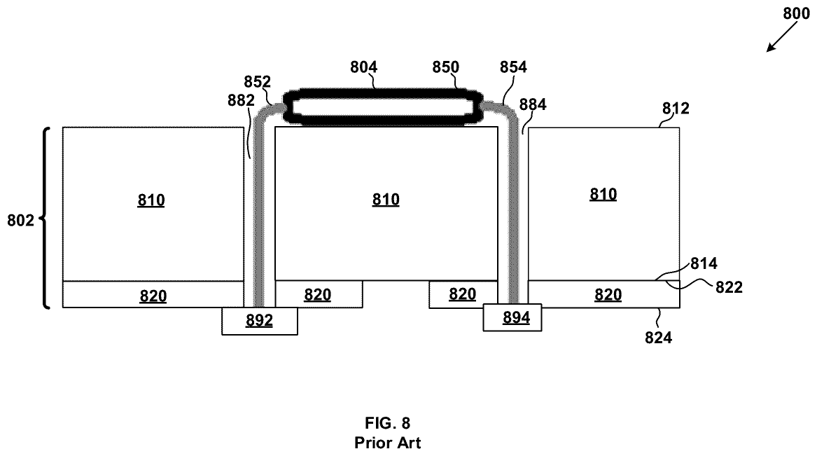

### 6. DETAILED DESCRIPTION OF THE DISCLOSURE

Certain embodiments of the present disclosure are directed to printed circuit board assemblies. More particularly, some embodiments of the disclosure provide printed circuit board assemblies with aluminum PCB substrates and methods thereof. Merely by way of example, some embodiments of the disclosure have been applied to home appliances. But it would be recognized that the disclosure has a much broader range of applicability.

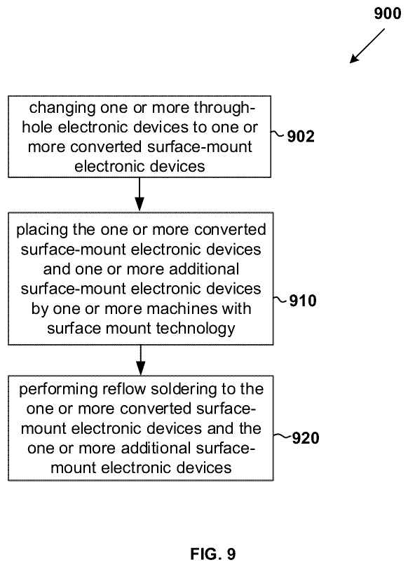

FIG. 9 is a simplified diagram showing a method for making a printed circuit board assembly (PCBA) with an aluminum PCB substrate used in a home appliance according to certain embodiments of the present disclosure. This diagram is merely an example, which should not unduly limit the scope of the claims. One of ordinary skill in the art would recognize many variations, alternatives, and modifications. The method 900 includes a process 902 for changing one or more through-hole electronic devices to one or more converted surface-mount electronic devices, a process 910 for placing the one or more converted surface-mount electronic devices and one or more additional surface-mount electronic devices by one or more machines with surface mount technology, and a process 920 for performing reflow soldering to the one or more converted surface-mount electronic devices and the one or more additional surface-mount electronic devices. For example, the home appliance is an induction cooker (e.g., an induction cooktop). As an example, the home appliance is an electric water heater. Although the above has been shown using a selected group of processes for the method, there can be many alternatives, modifications, and variations. For example, some of the processes may be expanded and/or combined. Other processes may be inserted to those noted above. Depending upon the embodiment, the sequence of processes may be interchanged with others replaced. Further details of these processes are found throughout the present specification.

At the process 902, one or more through-hole electronic devices are changed to one or more converted surface-mount electronic devices according to some embodiments. For example, the one or more through-hole electronic devices include a bridge rectifier, a resistor, a capacitor, an inductor, a transistor, a socket, and/or a connector. As an example, the one or more converted surface-mount electronic devices are one or more surface-mount electronic devices that are capable of being placed by one or more machines with surface mount technology.

At the process 910, the one or more converted surface-mount electronic devices are placed onto a surface (e.g., a top surface) of an aluminum PCB substrate by the one or more machines with surface mount technology according to certain embodiments. For example, the surface (e.g., a top surface) of the aluminum PCB substrate is opposite to another surface (e.g., a bottom surface) of the aluminum PCT substrate. As an example, the one or more converted surface-mount electronic devices are placed indirectly onto the surface (e.g., a top surface) of the aluminum PCB substrate.

In some examples, one or more additional surface-mount electronic devices are also placed onto the surface (e.g., a top surface) of the aluminum PCB substrate by the one or more machines with surface mount technology. For example, the one or more additional surface-mount electronic devices are placed indirectly onto the surface (e.g., a top surface) of the aluminum PCB substrate. In certain examples, the aluminum PCB substrate is made of aluminum.

At the process 920, reflow soldering is performed to the one or more converted surface-mount electronic devices and the one or more additional surface-mount electronic devices according to some embodiments.

As shown in FIG. 9, the processes 902, 910, and 920 of the method 900 are performed entirely by one or more machines, thus increasing the production efficiency and/or reducing the production costs and/or the defect rates according to certain embodiments.

As discussed above and further emphasized here, FIG. 9 is merely an example, which should not unduly limit the scope of the claims. One of ordinary skill in the art would recognize many variations, alternatives, and modifications. In some examples, after the process 920, one or more heat sinks are installed onto the aluminum PCB substrate. For example, the one or more heat sinks are installed onto a surface (e.g., a top surface) of the aluminum PCB substrate that is the same as the surface (e.g., a top surface) on which the one or more converted surface-mount electronic devices and the one or more additional surface-mount electronic devices are placed. As an example, the one or more heat sinks are installed onto a surface (e.g., a bottom surface) of the aluminum PCB substrate that is different from the surface (e.g., a top surface) on which the one or more converted surface-mount electronic devices and the one or more additional surface-mount electronic devices are placed. In certain examples, after the process 920, for at least one or more power electronic devices, the one or more heat sinks are installed onto the aluminum PCB substrate, wherein the one or more power electronic devices include one or more devices of the one or more converted surface-mount electronic devices and/or one or more devices of the one or more additional surface-mount electronic devices. In some examples, the aluminum PCB substrate is replaced by a PCB substrate that is made of one or more metals in addition to aluminum. In certain examples, the aluminum PCB substrate is replaced by a PCB substrate that is made of one or more metals, none of which is aluminum.

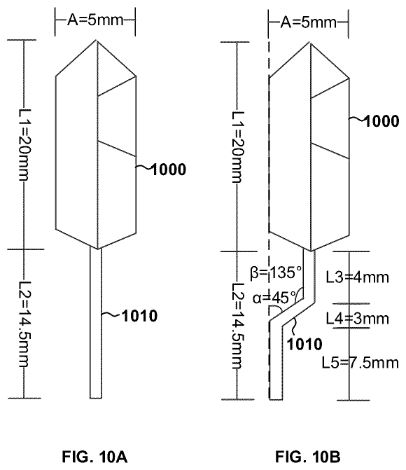

FIG. 10A and FIG. 10B are simplified diagrams showing the process 902 for changing an insulated-gate bipolar transistor from being a through-hole electronic device to being a converted surface-mount electronic device as part of the method 900 for making a printed circuit board assembly (PCBA) as shown in FIG. 9 according to some embodiments of the present disclosure. As shown in FIG. 10A and FIG. 10B, the process 902 is simple and reliable, thus suitable for mass production according to certain embodiments. These diagrams are merely examples, which should not unduly limit the scope of the claims. One of ordinary skill in the art would recognize many variations, alternatives, and modifications.

As shown in FIG. 10A, before the process 902 is performed, an insulated-gate bipolar transistor 1000 is a through-hole electronic device according to certain embodiments. For example, the insulated-gate bipolar transistor 1000 includes one or more pins 1010. As an example, the one or more pins 1010 are straight. As shown in FIG. 10B, at the process 902, the insulated-gate bipolar transistor 1000 is changed from being a through-hole electronic device to being a converted surface-mount electronic device according to some embodiments. For example, at the process 902, the one or more pins 1010 are bent. As an example, the bending process is performed by a customized tool.

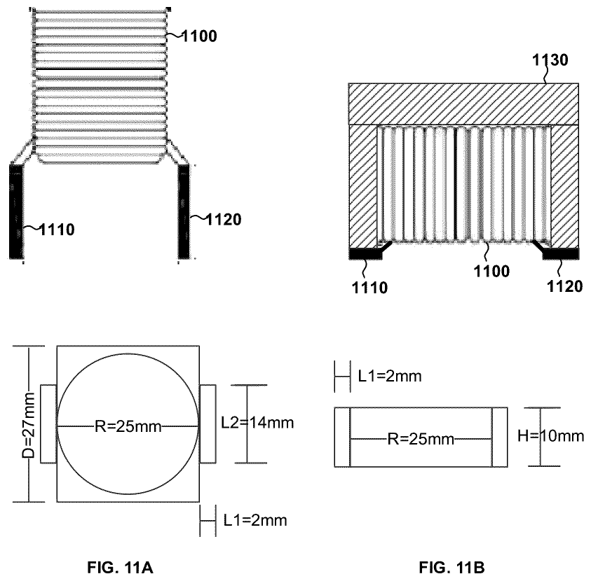

FIG. 11A and FIG. 11B are simplified diagrams showing the process 902 for changing an inductive winding from being a through-hole electronic device to being a converted surface-mount electronic device as part of the method 900 for making a printed circuit board assembly (PCBA) as shown in FIG. 9 according to certain embodiments of the present disclosure. These diagrams are merely examples, which should not unduly limit the scope of the claims. One of ordinary skill in the art would recognize many variations, alternatives, and modifications.

As shown in FIG. 11A, before the process 902 is performed, an inductive winding 1100 is a through-hole electronic device according to certain embodiments. For example, the inductive winding 1100 includes pins 1110 and 1120. As shown in FIG. 10B, at the process 902, the inductive winding 1100 is changed from being a through-hole electronic device to being a converted surface-mount electronic device according to some embodiments. In certain examples, the inductive winding 1100 is placed inside a housing 1130. For example, the housing 1130 is made of polyoxybenzylmethylenglycolanhydride and/or one or more other similar chemical compounds. As an example, the housing 1130 is fabricated by a molding method. In some examples, the pins 1110 and 1120 are bent. For example, the bending process is performed by a customized tool.

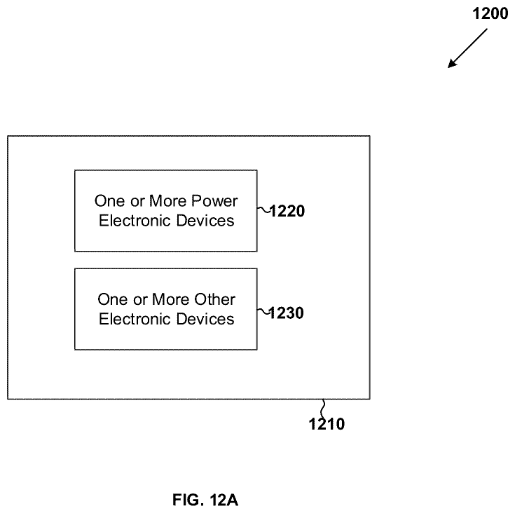

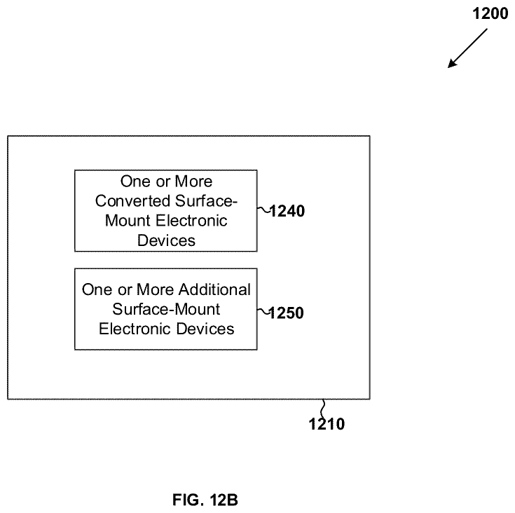

FIG. 12A and FIG. 12B are simplified diagrams showing a printed circuit board assembly (PCBA) with an aluminum PCB substrate that has been assembled by the method 900 as shown in FIG. 9 as part of a home appliance according to some embodiments of the present disclosure. This diagram is merely an example, which should not unduly limit the scope of the claims. One of ordinary skill in the art would recognize many variations, alternatives, and modifications. In some examples, the PCBA 1200 includes an aluminum PCB substrate 1210. For example, the aluminum PCB substrate 1210 is made of aluminum. In certain examples, the PCBA 1200 does not include any through-hole electronic device. For example, the home appliance is an induction cooker (e.g., an induction cooktop). As an example, the home appliance is an electric water heater. Although the above has been shown using a selected group of components for the printed circuit board assembly, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

As shown in FIG. 12A, the PCBA 1200 also includes one or more power electronic devices 1220 and one or more other electronic devices 1230 that are not power electronic devices according to some embodiments. For example, the PCBA 1200 does not include any heat sink. As an example, the PCBA 1200 includes one or more heat sinks (e.g., one or more small heat sinks) for one or more devices of the one or more power electronic devices 1220 (e.g., for one or more high power electronic devices). In certain examples, the one or more power electronic devices 1220 and the one or more other electronic devices 1230 are assembled onto the aluminum PCB substrate 1210. For example, the aluminum PCB substrate 1210 is made of aluminum. In some examples, the aluminum PCB substrate 1210) achieves good heat dissipation without any need to include any heat sink for the one or more power electronic devices 1220, even though the one or more power electronic devices 1220 generate significant heat during operation due to one or more large currents.

As shown in FIG. 12B, the PCBA 1200 also includes one or more converted surface-mount electronic devices 1240) and one or more additional surface-mount electronic devices 1250 according to certain embodiments. For example, the one or more converted surface-mount electronic devices 1240 are generated by the process 902 of the method 900. In some examples, the one or more converted surface-mount electronic devices 1240) as shown in FIG. 12B include some of the one or more power electronic devices 1220 as shown in FIG. 12A and/or some of the one or more other electronic devices 1230 that are not power electronic devices as shown in FIG. 12A. For example, none of the one or more converted surface-mount electronic devices 1240) as shown in FIG. 12B are in contact with any heat sinks. As an example, one or more devices of the one or more converted surface-mount electronic devices 1240) as shown in FIG. 12B are in contact with one or more heat sinks. In certain examples, the one or more additional surface-mount electronic devices 1250 as shown in FIG. 12B include some of the one or more power electronic devices 1220 as shown in FIG. 12A and/or some of the one or more other electronic devices 1230 that are not power electronic devices as shown in FIG. 12A. For example, none of the one or more additional surface-mount electronic devices 1250 as shown in FIG. 12B are in contact with any heat sinks. As an example, one or more devices of the one or more additional surface-mount electronic devices 1250 as shown in FIG. 12B are in contact with one or more heat sinks.

As discussed above and further emphasized here. FIG. 12A and FIG. 12B are merely examples, which should not unduly limit the scope of the claims. One of ordinary skill in the art would recognize many variations, alternatives, and modifications. In some embodiments, the one or more power electronic devices 1220 include an insulated-gate bipolar transistor. In certain examples, the insulated-gate bipolar transistor is placed on an edge region of the aluminum PCB substrate 1210, away from other heat-generating electronic devices. For example, placing the insulated-gate bipolar transistor on the edge region improves heat dissipation from the insulated-gate bipolar transistor and also prevents the heat generated by the insulated-gate bipolar transistor from affecting other electronic devices. In certain embodiments, a package that contains the insulated-gate bipolar transistor on the aluminum PCB substrate 1210 is larger than the insulated-gate bipolar transistor itself. For example, the larger package for the insulated-gate bipolar transistor increases the contact area between the insulated-gate bipolar transistor and the aluminum PCB substrate 1210. As an example, the increased contact area accelerates the heat transfer from the insulated-gate bipolar transistor to the aluminum PCB substrate 1210. In some embodiments, in addition to the one or more converted surface-mount electronic devices 1240) and the one or more additional surface-mount electronic devices 1250, the PCBA 1200 also includes one or more through-hole electronic devices that are not converted to any surface-mount electronic devices. In certain examples, the aluminum PCB substrate 1210 is replaced by a PCB substrate that is made of one or more metals in addition to aluminum. In some examples, the aluminum PCB substrate 1210 is replaced by a PCB substrate that is made of one or more metals, none of which is aluminum.

In some embodiments, the thermal conductivity of an epoxy resin substrate is about 0.3 W/m·K but the thermal conductivity of an aluminum substrate is about 2.0 W/m·K, so at the same substrate thickness, the thermal conduction efficiency of the aluminum substrate is about 7 times as much as the thermal conduction efficiency of the epoxy resin substrate. In certain embodiments, by adjusting thickness, one or more openings, and/or distribution of one or more power electronic devices, the thermal conduction efficiency of the aluminum substrate reaches about 10 times as much as the thermal conduction efficiency of the epoxy resin substrate.

According to certain embodiments, when an aluminum substrate is used as a PCB substrate, one or more heat sinks that would have been needed when an epoxy resin PCB substrate is used are no longer needed. For example, when an aluminum substrate is used as a PCB substrate, no heat sink needs to be installed for power electronic devices. As an example, when an aluminum substrate is used as a PCB substrate, fewer but some heat sinks are still installed for some power electronic devices.

According to some embodiments, the process of installing one or more heat sinks through manual operation is eliminated. For example, the elimination of installation of one or more heat sinks for one or more power electronic devices improves the production efficiency and/or reduces the production costs and/or the defect rates. As an example, the elimination of installation of one or more heat sinks for one or more power electronic devices helps solve the problem of irregular shapes in the PCBA.

Some embodiments of the present disclosure provide a printed circuit board assembly that includes an aluminum substrate as a PCB substrate and an insulated-gate bipolar transistor as a converted surface-mount electronic device in order to accelerate the heat dissipation of the insulated-gate bipolar transistor through the entire surface of the aluminum substrate. For example, the use of an aluminum substrate as a PCB substrate provides a better heat dissipation channel for one or more high-heat-generating devices (e.g., one or more power electronic devices) than the use of an epoxy resin substrate as the PCB substrate. As an example, the one or more high-heat-generating devices includes an insulated-gate bipolar transistor.

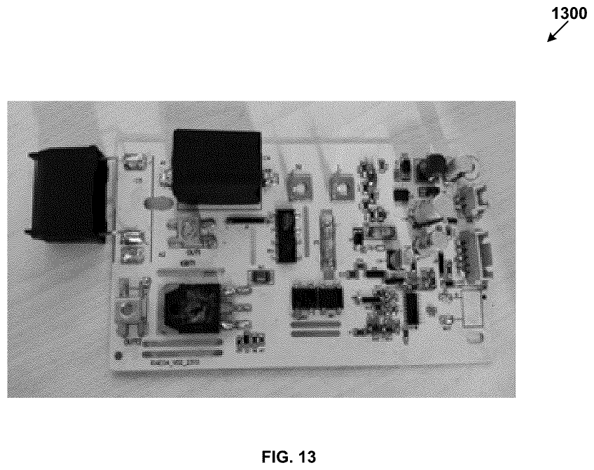

FIG. 13 is a simplified diagram showing a printed circuit board assembly (PCBA) with an aluminum PCB substrate that has been assembled by the method 900 as shown in FIG. 9 as part of an induction cooker (e.g., an induction cooktop) according to certain embodiments of the present disclosure. This diagram is merely an example, which should not unduly limit the scope of the claims. One of ordinary skill in the art would recognize many variations, alternatives, and modifications. In some examples, the PCBA 1300 includes an aluminum PCB substrate. For example, the aluminum PCB substrate is made of aluminum. In certain examples, the PCBA 1300 does not include any through-hole electronic device. Although the above has been shown using a selected group of components for the printed circuit board assembly, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

According to some embodiments, the PCBA 1300 also includes one or more power electronic devices and one or more other electronic devices that are not power electronic devices. For example, the PCBA 1300 does not include any heat sink. As an example, the PCBA 1300 includes one or more heat sinks (e.g., one or more small heat sinks) for one or more devices of the one or more power electronic devices (e.g., for one or more high power electronic devices). In certain examples, the one or more power electronic devices and the one or more other electronic devices are assembled onto the aluminum PCB substrate. In some examples, the aluminum PCB substrate achieves good heat dissipation without any need to include one or more heat sinks for one or more power electronic devices, even though the one or more power electronic devices generate significant heat during operation due to one or more large currents.

According to certain embodiments, the PCBA 1300 includes one or more converted surface-mount electronic devices and one or more additional surface-mount electronic devices. For example, the one or more converted surface-mount electronic devices are generated by the process 902 of the method 900. In some examples, the one or more converted surface-mount electronic devices include some of the one or more power electronic devices and/or some of the one or more other electronic devices that are not power electronic devices. For example, none of the one or more converted surface-mount electronic devices are in contact with any heat sink. As an example, one or more devices of the one or more converted surface-mount electronic devices are in contact with one or more heat sinks. In certain examples, the one or more additional surface-mount electronic devices include some of the one or more power electronic devices and/or some of the one or more other electronic devices that are not power electronic devices. For example, none of the one or more additional surface-mount electronic devices is in contact with any heat sink. As an example, one or more devices of the one or more additional surface-mount electronic devices are in contact with one or more heat sinks. As shown in FIG. 13, the PCBA 1300 is an example of the PCBA 1200 as shown in FIG. 12A and FIG. 12B according to some embodiments.

As discussed above and further emphasized here, FIG. 13 is merely an example, which should not unduly limit the scope of the claims. One of ordinary skill in the art would recognize many variations, alternatives, and modifications. In some embodiments, in addition to the one or more converted surface-mount electronic devices and the one or more additional surface-mount electronic devices, the PCBA 1300 also includes one or more through-hole electronic devices that are not converted to any surface-mount electronic devices. For example, the aluminum PCB substrate is replaced by a PCB substrate that is made of one or more metals in addition to aluminum. As an example, the aluminum PCB substrate is replaced by a PCB substrate that is made of one or more metals, none of which is aluminum.

In certain embodiments, a printed circuit board assembly includes a PCB substrate, one or more converted surface-mount electronic devices, and one or more additional surface-mount electronic devices, wherein the one or more converted surface-mount electronic devices are obtained by changing one or more through-hole electronic devices, and the one or more converted surface-mount electronic devices can be placed by one or more machines with surface mount technology. For example, the PCB substrate is a metal substrate (e.g., an aluminum substrate). In some examples, the one or more converted surface-mount electronic devices include an insulated-gate bipolar transistor that has been changed from being a through-hole electronic device to being a converted surface-mount electronic device by bending one or more pins of the insulated-gate bipolar transistor, and/or an inductive winding that has been changed from being a through-hole electronic device to being a converted surface-mount electronic device by placing the inductive winding inside a housing and bending one or more pins of the inductive winding. For example, the insulated-gate bipolar transistor is placed on an edge region of a PCB substrate. As an example, a package that contains the insulated-gate bipolar transistor on the PCB substrate is larger than the insulated-gate bipolar transistor itself.

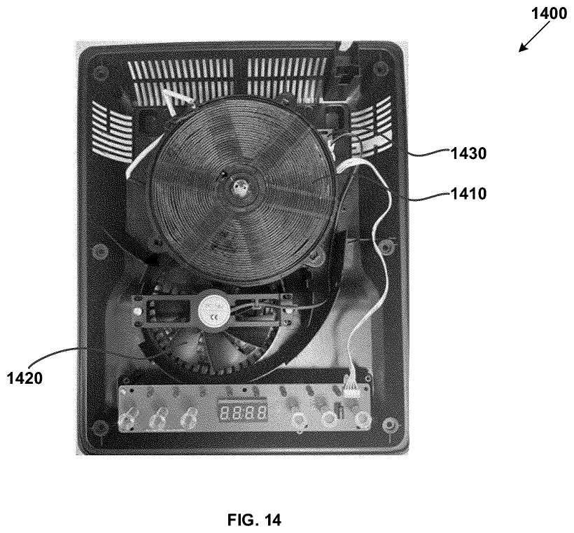

FIG. 14 is a simplified diagram showing certain components of an induction cooker that includes a printed circuit board assembly (PCBA) with an aluminum PCB substrate according to certain embodiments of the present disclosure. This diagram is merely an example, which should not unduly limit the scope of the claims. One of ordinary skill in the art would recognize many variations, alternatives, and modifications. The induction cooker 1400 (e.g., an induction cooktop) includes a coil 1410, a fan 1420, and a printed circuit board assembly (PCBA) 1430 that includes an aluminum PCB substrate. For example, the coil 1410 is used to generate a magnetic field. As an example, the fan 1420 is used for cooling. For example, the aluminum PCB substrate is made of aluminum. Although the above has been shown using a selected group of components for the induction cooker, there can be many alternatives, modifications, and variations. For example, some of the components may be expanded and/or combined. Other components may be inserted to those noted above. Depending upon the embodiment, the arrangement of components may be interchanged with others replaced. In certain examples, the aluminum PCB substrate is replaced by a PCB substrate that is made of one or more metals in addition to aluminum. In some examples, the aluminum PCB substrate is replaced by a PCB substrate that is made of one or more metals, none of which is aluminum. Further details of these components are found throughout the present specification.

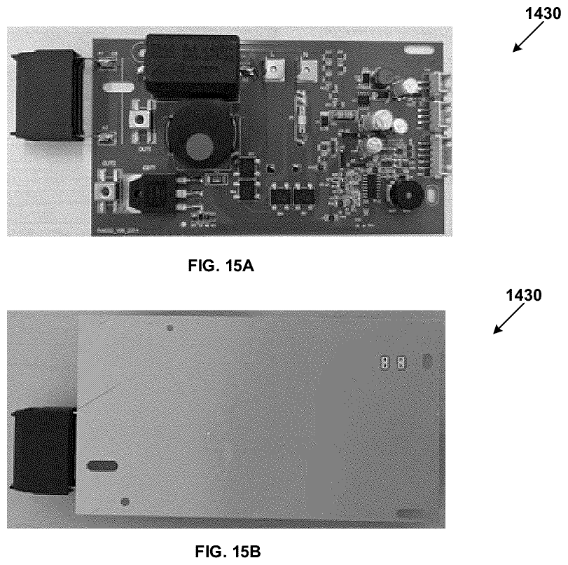

FIG. 15A and FIG. 15B are simplified diagrams showing the printed circuit board assembly (PCBA) 1430 as part of the induction cooker 1400 as shown in FIG. 14 according to some embodiments of the present disclosure. These diagrams are merely examples, which should not unduly limit the scope of the claims. One of ordinary skill in the art would recognize many variations, alternatives, and modifications. In certain examples, FIG. 15A shows a top view of the PCBA 1430, and FIG. 15B shows a bottom view of the PCBA 1430. For example, the PCBA 1430 as shown in FIG. 15A and FIG. 15B is the PCBA 1200 as shown in FIG. 12A and FIG. 12B. As an example, the PCBA 1430 as shown in FIG. 15A and FIG. 15B is the PCBA 1300 as shown in FIG. 13.

As shown in FIG. 15A and FIG. 15B, the PCBA 1430 includes an aluminum PCB substrate according to certain embodiments. For example, the aluminum PCB substrate is made of aluminum. In some examples, as shown in FIG. 15A, the PCBA 1430) also includes one or more converted surface-mount electronic devices and one or more additional surface-mount electronic devices. For example, the one or more converted surface-mount electronic devices and the one or more additional surface-mount electronic devices are placed on a top surface of the aluminum PCB substrate. In certain examples, as shown in FIG. 15B, the PCBA 1430 does not include any through-hole electronic device. For example, there is no solder block that is attached to a bottom surface of the aluminum PCB substrate.

As discussed above and further emphasized here. FIG. 15A and FIG. 15B are merely examples, which should not unduly limit the scope of the claims. One of ordinary skill in the art would recognize many variations, alternatives, and modifications. For example, the aluminum PCB substrate of the PCBA 1430 is replaced by a PCB substrate that is made of one or more metals in addition to aluminum. As an example, the aluminum PCB substrate of the PCBA 1430 is replaced by a PCB substrate that is made of one or more metals, none of which is aluminum.

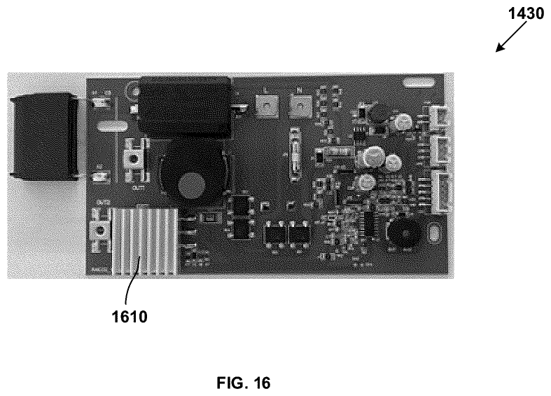

FIG. 16 is a simplified diagram showing the printed circuit board assembly (PCBA) 1430 as part of the induction cooker 1400 as shown in FIG. 14 according to certain embodiments of the present disclosure. This diagram is merely an example, which should not unduly limit the scope of the claims. One of ordinary skill in the art would recognize many variations, alternatives, and modifications. For example, the PCBA 1430 as shown in FIG. 16 is the PCBA 1200 as shown in FIG. 12A and FIG. 12B. As an example, the PCBA 1430 as shown in FIG. 16 is the PCBA 1300 as shown in FIG. 13.

As shown in FIG. 16, the PCBA 1430 includes an aluminum PCB substrate according to some embodiments. For example, the aluminum PCB substrate is made of aluminum. In certain examples, as shown in FIG. 16, the PCBA 1430 also includes one or more converted surface-mount electronic devices and one or more additional surface-mount electronic devices. For example, the one or more converted surface-mount electronic devices and the one or more additional surface-mount electronic devices are placed on a top surface of the aluminum PCB substrate. In some examples, as shown in FIG. 16, the PCBA 1430) also includes a heat sink 1610 on the top surface of the aluminum PCB substrate. In certain embodiments, the PCBA 1430 as shown in FIG. 16 is made by adding the heat sink 1610 to the PCBA 1430 as shown in FIG. 15A and FIG. 15B. For example, the PCBA 1430 as shown in FIG. 16 does not include any through-hole electronic device. As an example, there is no solder block that is attached to a bottom surface of the aluminum PCB substrate.

As discussed above and further emphasized here. FIG. 16 is merely an example, which should not unduly limit the scope of the claims. One of ordinary skill in the art would recognize many variations, alternatives, and modifications. For example, the aluminum PCB substrate of the PCBA 1430 is replaced by a PCB substrate that is made of one or more metals in addition to aluminum. As an example, the aluminum PCB substrate of the PCBA 1430 is replaced by a PCB substrate that is made of one or more metals, none of which is aluminum.

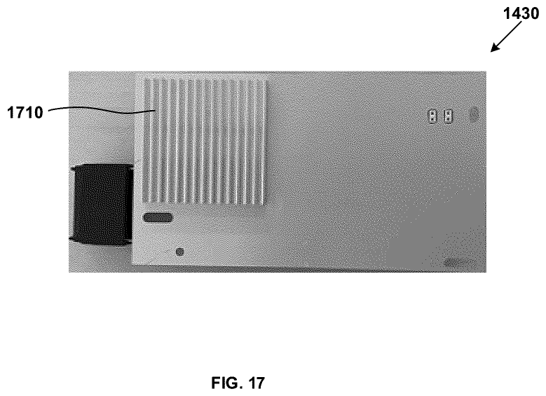

FIG. 17 is a simplified diagram showing the printed circuit board assembly (PCBA) 1430 as part of the induction cooker 1400 as shown in FIG. 14 according to certain embodiments of the present disclosure. This diagram is merely an example, which should not unduly limit the scope of the claims. One of ordinary skill in the art would recognize many variations, alternatives, and modifications. For example, the PCBA 1430 as shown in FIG. 17 is the PCBA 1200 as shown in FIG. 12A and FIG. 12B. As an example, the PCBA 1430 as shown in FIG. 17 is the PCBA 1300 as shown in FIG. 13.

As shown in FIG. 17, the PCBA 1430 includes an aluminum PCB substrate according to some embodiments. For example, the aluminum PCB substrate is made of aluminum. In certain examples, as shown in FIG. 17, the PCBA 1430 also includes one or more converted surface-mount electronic devices and one or more additional surface-mount electronic devices. For example, the one or more converted surface-mount electronic devices and the one or more additional surface-mount electronic devices are placed on a top surface of the aluminum PCB substrate. In some examples, as shown in FIG. 17, the PCBA 1430) also includes a heat sink 1710 that is attached, directly or indirectly, to a bottom surface of the aluminum PCB substrate. For example, the bottom surface of the aluminum PCB substrate and the top surface of the aluminum PCB substrate are opposite to each other. In certain embodiments, the PCBA 1430 as shown in FIG. 17 is made by adding the heat sink 1710 to the PCBA 1430 as shown in FIG. 15A and FIG. 15B. For example, the PCBA 1430) as shown in FIG. 17 does not include any through-hole electronic device.

As discussed above and further emphasized here, FIG. 17 is merely an example, which should not unduly limit the scope of the claims. One of ordinary skill in the art would recognize many variations, alternatives, and modifications. For example, the aluminum PCB substrate of the PCBA 1430 is replaced by a PCB substrate that is made of one or more metals in addition to aluminum. As an example, the aluminum PCB substrate of the PCBA 1430 is replaced by a PCB substrate that is made of one or more metals, none of which is aluminum.

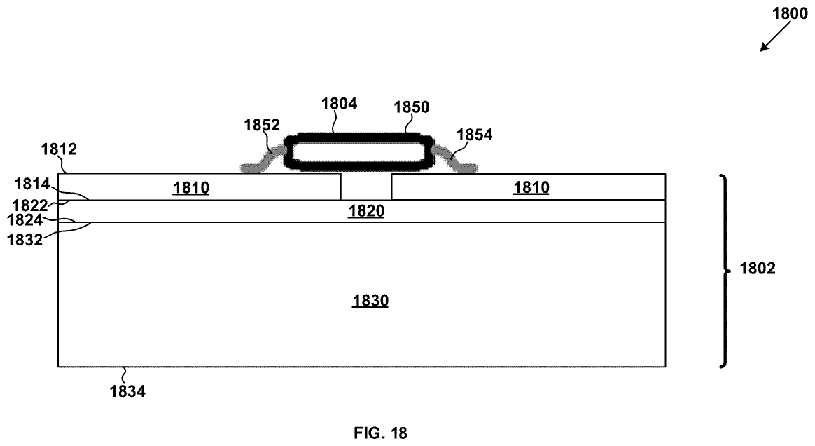

FIG. 18 is a simplified diagram showing a printed circuit board assembly (PCBA) with an aluminum PCB substrate according to some embodiments of the present disclosure. This diagram is merely an example, which should not unduly limit the scope of the claims. One of ordinary skill in the art would recognize many variations, alternatives, and modifications. In certain examples. FIG. 18 shows a section view of the printed circuit board assembly (PCBA) 1800. The printed circuit board assembly (PCBA) 1800 includes a printed circuit board (PCB) 1802 and one or more electronic devices 1804. In some examples, the PCB 1802 includes a conductive layer 1810, an insulating layer 1820, and an aluminum PCB substrate 1830. For example, the PCBA 1800 is the PCBA 1200 as shown in FIG. 12A and FIG. 12B. As an example, the PCBA 1800 is the PCBA 1300 as shown in FIG. 13. For example, the PCBA 1800 is the PCBA 1430 as shown in FIG. 15A and FIG. 15B. As an example, the PCBA 1800 is the PCBA 1430 as shown in FIG. 16. For example, the PCBA 1800 is the PCBA 1430 as shown in FIG. 17. In some examples, the PCBA 1800 is part of a home appliance. For example, the PCBA 1800 is part of an induction cooker (e.g., an induction cooktop). As an example, the PCBA 1800 is part of an electric water heater.

In certain embodiments, the PCB 1802 includes the conductive layer 1810 that is made of one or more conductive materials. For example, the conductive layer 1810 is made of copper. As an example, the conductive layer 1810 includes one or more copper foils. For example, the conductive layer 1810 is used as a routing layer. In some examples, the conductive layer 1810 includes a top surface 1812 and a bottom surface 1814. For example, the top surface 1812 and the bottom surface 1814 are opposite to each other. In some embodiments, the PCB 1802 includes the insulating layer 1820 that is made of one or more insulating materials. For example, the insulating layer 1820 is made of epoxy resin. As an example, the insulating layer 1820 is made of fiberglass. For example, the insulating layer 1820 is made of epoxy resin and fiberglass. As an example, the insulating layer 1820 is made of one or more glass-reinforced epoxy laminate materials (e.g., FR-4). For example, the insulating layer 1820 is made of one or more ceramics. As an example, the insulating layer 1820 is made of one or more polymer compounds. In certain examples, the insulating layer 1820 includes a top surface 1822 and a bottom surface 1824. As an example, the top surface 1822 and the bottom surface 1824 are opposite to each other. For example, the top surface 1822 of the insulating layer 1820 is, directly or indirectly, in contact with the bottom surface 1814 of the conductive layer 1810. As an example, the conductive layer 1810 is on the insulating layer 1820 (e.g., directly or indirectly on the insulating layer 1820). In certain embodiments, the PCB 1802 includes the aluminum PCB substrate 1830 that is made of aluminum. In some examples, the aluminum PCB substrate 1830) includes a top surface 1832 and a bottom surface 1834. As an example, the top surface 1832 and the bottom surface 1834 are opposite to each other. For example, the top surface 1832 of the aluminum PCB substrate 1830 is, directly or indirectly, in contact with the bottom surface 1824 of the insulating layer 1820. As an example, the insulating layer 1820 is on the aluminum PCB substrate 1830 (e.g., directly or indirectly on the aluminum PCB substrate 1830). For example, the aluminum PCB substrate 1830 is made of aluminum.

According to some embodiments, the one or more electronic devices 1804 include one or more surface-mount electronic devices that include a surface-mount electronic device 1850 (e.g., a converted surface-mount electronic device). For example, the surface-mount electronic device 1850 includes pins 1852 and 1854. As an example, the surface-mount electronic device 1850 is a converted surface-mount electronic device, and the pins 1852 and 1854 are bent. According to certain embodiments, the surface-mount electronic device 1850) is placed on the top surface 1812 of the conductive layer 1810. For example, the pins 1852 and 1854 of the surface-mount electronic device 1850 are attached, directly or indirectly, to the top surface 1812 of the conductive layer 1810. As an example, the one or more electronic devices 1804 (e.g., one or more surface-mount electronic devices) are on the aluminum PCB substrate 1830 through the conductive layer 1810 and the insulating layer 1820. For example, the surface-mount electronic device 1850) (e.g., a converted surface-mount electronic device) is on the aluminum PCB substrate 1830 through the conductive layer 1810 and the insulating layer 1820.

According to certain embodiments, the surface-mount electronic device 1850 is a converted surface-mount electronic device. In some examples, the converted surface-mount electronic device 1850 is not a power electronic device. In certain examples, the converted surface-mount electronic device 1850 is a power electronic device. For example, the power electronic device 1850 is not in direct contact with any heat sink. As an example, the power electronic device 1850 is in contact with one or more heat sinks.

In some embodiments, the PCBA 1800 includes one or more heat sinks, in addition to the printed circuit board (PCB) 1802 and the one or more electronic devices 1804. In certain examples, the one or more heat sinks are in contact with the one or more electronic devices 1804 (e.g., one or more surface-mount electronic devices). For example, the one or more heat sinks are in contact with the converted surface-mount electronic device 1850 (e.g., a power electronic device). In some examples, the one or more heat sinks are not in direct contact with any of the one or more electronic devices 1804 (e.g., one or more surface-mount electronic devices). As an example, the one or more heat sinks are not in direct contact with the converted surface-mount electronic device 1850) (e.g., a power electronic device). In certain examples, the one or more heat sinks are attached to the top surface 1832 of the aluminum PCB substrate 1830 through the conductive layer 1810 and the insulating layer 1820. For example, the one or more heat sinks are on the top surface 1832 of the aluminum PCB substrate 1830 (e.g., on the top surface 1832 of the aluminum PCB substrate 1830) through the conductive layer 1810 and the insulating layer 1820). In some examples, the one or more heat sinks are attached to the bottom surface 1834 of the aluminum PCB substrate 1830. For example, the one or more heat sinks are in direct contact with the bottom surface 1834 of the aluminum PCB substrate 1830.

As discussed above and further emphasized here, FIG. 18 is merely an example, which should not unduly limit the scope of the claims. One of ordinary skill in the art would recognize many variations, alternatives, and modifications. For example, the aluminum PCB substrate 1830 is replaced by a PCB substrate that is made of one or more metals in addition to aluminum. As an example, the aluminum PCB substrate 1830 is replaced by a PCB substrate that is made of one or more metals, none of which is aluminum.

According to certain embodiments, a printed circuit board assembly includes: an aluminum substrate; an insulating layer on the aluminum substrate; a conductive layer on the insulating layer; and one or more surface-mount electronic devices on the aluminum substrate through the conductive layer and the insulating layer; wherein: the one or more surface-mount electronic devices include at least one converted surface-mount electronic device, the one converted surface-mount electronic device being converted from a through-hole electronic device; and the one converted surface-mount electronic device is on the aluminum substrate through the conductive layer and the insulating layer; wherein the aluminum substrate is made of aluminum. For example, the printed circuit board assembly is implemented according to at least FIG. 18. As an example, the printed circuit board assembly is implemented according to at least FIG. 12A, FIG. 12B, FIG. 13, FIG. 15A, FIG. 15B. FIG. 16, FIG. 17, and/or FIG. 18.

For example, the aluminum substrate includes a first surface and a second surface; the insulating layer includes a third surface and a fourth surface; and the conductive layer includes a fifth surface and a sixth surface; wherein: the second surface of the aluminum substrate is in direct or indirect contact with the third surface of the insulating layer; and the fourth surface of the insulating layer is in direct or indirect contact with the fifth surface of the conductive layer. As an example, the one converted surface-mount electronic device is on the sixth surface of the conductive layer. For example, the printed circuit board assembly does not include any through-hole electronic device. As an example, the printed circuit board assembly further includes one or more through-hole electronic devices. For example, the one converted surface-mount electronic device is not a power electronic device. As an example, the one converted surface-mount electronic device is a power electronic device; and the power electronic device is not in direct contact with any heat sink. For example, the printed circuit board assembly does not include any heat sink.

As an example, the printed circuit board assembly further includes a heat sink. For example, the heat sink is not in direct contact with any of the one or more surface-mount electronic devices. As an example, the one converted surface-mount electronic device is a power electronic device; and the power electronic device is in contact with the heat sink. For example, the aluminum substrate includes a first surface and a second surface; the insulating layer includes a third surface and a fourth surface; and the conductive layer includes a fifth surface and a sixth surface; wherein: the second surface of the aluminum substrate is in direct or indirect contact with the third surface of the insulating layer; and the fourth surface of the insulating layer is in direct or indirect contact with the fifth surface of the conductive layer. As an example, the heat sink is attached to the second surface of the aluminum substrate through the conductive layer and the insulating layer. For example, wherein the heat sink is attached to the first surface of the aluminum substrate. As an example, the one converted surface-mount electronic device is an insulated-gate bipolar transistor that has been converted from being a through-hole electronic device. For example, the one converted surface-mount electronic device is an inductive winding that has been converted from being a through-hole electronic device.

According to some embodiments, a printed circuit board assembly of a home appliance includes: an aluminum substrate including a first substrate surface and a second substrate surface, the first substrate surface and the second substrate surface being opposite to each other; one or more converted surface-mount electronic devices on the first substrate surface of the aluminum substrate, the one or more converted surface-mount electronic devices being converted from one or more first through-hole electronic devices; and one or more additional surface-mount electronic devices on the first substrate surface of the aluminum substrate; wherein the aluminum substrate is made of aluminum. For example, the printed circuit board assembly is implemented according to at least FIG. 18. As an example, the printed circuit board assembly is implemented according to at least FIG. 12A, FIG. 12B. FIG. 13, FIG. 15A, FIG. 15B, FIG. 16, FIG. 17, and/or FIG. 18.

For example, the printed circuit board assembly does not include any through-hole electronic device. As an example, the printed circuit board assembly further includes: one or more second through-hole electronic devices. For example, the one or more converted surface-mount electronic devices include one or more power electronic devices; and the one or more power electronic devices are not in direct contact with any heat sink. As an example, the printed circuit board assembly does not include any heat sink. For example, the printed circuit board assembly further includes one or more heat sinks. As an example, the one or more heat sinks are not in direct contact with any of the one or more converted surface-mount electronic devices and are not in direct contact with any of the one or more additional surface-mount electronic devices. For example, the one or more heat sinks are located on the first substrate surface of the aluminum substrate. As an example, the one or more heat sinks are attached to the second substrate surface of the aluminum substrate. For example, the one or more heat sinks are in direct contact with the second substrate surface of the aluminum substrate.

As an example, the one or more converted surface-mount electronic devices include one or more power electronic devices; and one or more devices of the one or more power electronic devices are in contact with one or more heat sinks. For example, the one or more converted surface-mount electronic devices include an insulated-gate bipolar transistor that has been converted from being a through-hole electronic device to being a converted surface-mount electronic device. As an example, the one or more converted surface-mount electronic devices include an inductive winding that has been converted from being a through-hole electronic device to being a converted surface-mount electronic device. For example, the home appliance is an induction cooker. As an example, the home appliance is an electric water heater.

According to certain embodiments, an induction cooker includes: a printed circuit board assembly; wherein the printed circuit board assembly includes: an aluminum substrate; an insulating layer on the aluminum substrate; a conductive layer on the insulating layer; and one or more surface-mount electronic devices on the aluminum substrate through the conductive layer and the insulating layer; wherein: the one or more surface-mount electronic devices include at least one converted surface-mount electronic device, the one converted surface-mount electronic device being converted from a through-hole electronic device; and the one converted surface-mount electronic device is on the aluminum substrate through the conductive layer and the insulating layer; wherein the aluminum substrate is made of aluminum. For example, the induction cooker is implemented according to at least FIG. 14, FIG. 12A, FIG. 12B, FIG. 13, FIG. 15A, FIG. 15B, FIG. 16, FIG. 17, and/or FIG. 18.

As an example, the aluminum substrate includes a first surface and a second surface; the insulating layer includes a third surface and a fourth surface; and the conductive layer includes a fifth surface and a sixth surface; wherein: the second surface of the aluminum substrate is in direct or indirect contact with the third surface of the insulating layer; and the fourth surface of the insulating layer is in direct or indirect contact with the fifth surface of the conductive layer. For example, the one converted surface-mount electronic device is on the sixth surface of the conductive layer. As an example, the printed circuit board assembly does not include any through-hole electronic device. For example, the printed circuit board assembly further includes one or more through-hole electronic devices. As an example, the one converted surface-mount electronic device is not a power electronic device. For example, the one converted surface-mount electronic device is a power electronic device; and the power electronic device is not in direct contact with any heat sink. As an example, the printed circuit board assembly does not include any heat sink.

For example, the printed circuit board assembly further includes a heat sink. As an example, the heat sink is not in direct contact with any of the one or more surface-mount electronic devices. For example, the one converted surface-mount electronic device is a power electronic device; and the power electronic device is in contact with the heat sink. As an example, the aluminum substrate includes a first surface and a second surface; the insulating layer includes a third surface and a fourth surface; and the conductive layer includes a fifth surface and a sixth surface; wherein: the second surface of the aluminum substrate is in direct or indirect contact with the third surface of the insulating layer; and the fourth surface of the insulating layer is in direct or indirect contact with the fifth surface of the conductive layer. For example, the heat sink is attached to the second surface of the aluminum substrate through the conductive layer and the insulating layer. As an example, the heat sink is attached to the first surface of the aluminum substrate. For example, the one converted surface-mount electronic device is an insulated-gate bipolar transistor that has been converted from being a through-hole electronic device. As an example, the one converted surface-mount electronic device is an inductive winding that has been converted from being a through-hole electronic device.

According to some embodiments, an induction cooker includes: a printed circuit board assembly; wherein the printed circuit board assembly includes: an aluminum substrate including a first substrate surface and a second substrate surface, the first substrate surface and the second substrate surface being opposite to each other; one or more converted surface-mount electronic devices on the first substrate surface of the aluminum substrate, the one or more converted surface-mount electronic devices being converted from one or more first through-hole electronic devices; and one or more additional surface-mount electronic devices on the first substrate surface of the aluminum substrate; wherein the aluminum substrate is made of aluminum. For example, the induction cooker is implemented according to at least FIG. 14, FIG. 12A, FIG. 12B, FIG. 13, FIG. 15A, FIG. 15B, FIG. 16, FIG. 17, and/or FIG. 18.

As an example, the printed circuit board assembly does not include any through-hole electronic device. For example, the printed circuit board assembly further includes one or more second through-hole electronic devices. As an example, the one or more converted surface-mount electronic devices include one or more power electronic devices; and the one or more power electronic devices are not in direct contact with any heat sink. For example, the printed circuit board assembly does not include any heat sink. As an example, the printed circuit board assembly further includes one or more heat sinks. For example, the one or more heat sinks are not in direct contact with any of the one or more converted surface-mount electronic devices and are not in direct contact with any of the one or more additional surface-mount electronic devices. As an example, the one or more heat sinks are located on the first substrate surface of the aluminum substrate. For example, the one or more heat sinks are attached to the second substrate surface of the aluminum substrate. As an example, the one or more heat sinks are in direct contact with the second substrate surface of the aluminum substrate.

For example, the one or more converted surface-mount electronic devices include one or more power electronic devices; and one or more devices of the one or more power electronic devices are in contact with one or more heat sinks. As an example, the one or more converted surface-mount electronic devices include an insulated-gate bipolar transistor that has been converted from being a through-hole electronic device to being a converted surface-mount electronic device. For example, the one or more converted surface-mount electronic devices include an inductive winding that has been converted from being a through-hole electronic device to being a converted surface-mount electronic device.

According to certain embodiments, a method for making a printed circuit board assembly (PCBA) of a home appliance includes: changing one or more through-hole electronic devices to one or more converted surface-mount electronic devices; placing the one or more converted surface-mount electronic devices and one or more additional surface-mount electronic devices onto an aluminum PCB substrate by one or more machines with surface mount technology; and performing reflow soldering to the one or more converted surface-mount electronic devices and the one or more additional surface-mount electronic devices; wherein the aluminum PCB substrate is made of aluminum. For example, the method is implemented according to at least FIG. 9.

As an example, the changing one or more through-hole electronic devices to one or more converted surface-mount electronic devices includes: changing an insulated-gate bipolar transistor from being a through-hole electronic device to being a converted surface-mount electronic device: wherein the insulated-gate bipolar transistor includes one or more pins. For example, the changing an insulated-gate bipolar transistor from being a through-hole electronic device to being a converted surface-mount electronic device includes: bending the one or more pins of the insulated-gate bipolar transistor so that the insulated-gate bipolar transistor changes from being the through-hole electronic device to being the converted surface-mount electronic device. As an example, the changing an insulated-gate bipolar transistor from being a through-hole electronic device to being a converted surface-mount electronic device further includes: placing the insulated-gate bipolar transistor into a package that is larger than the insulated-gate bipolar transistor itself. For example, the placing the one or more converted surface-mount electronic devices and one or more additional surface-mount electronic devices onto an aluminum PCB substrate by one or more machines with surface mount technology includes: placing the insulated-gate bipolar transistor as the converted surface-mount electronic device on an edge region of the aluminum PCB substrate.

As an example, the changing one or more through-hole electronic devices to one or more converted surface-mount electronic devices includes: changing an inductive winding from being a through-hole electronic device to being a converted surface-mount electronic device: wherein the inductive winding includes a first pin and a second pin. For example, the changing an inductive winding from being a through-hole electronic device to being a converted surface-mount electronic device includes: placing the inductive winding inside a housing; and bending the first pin and the second pin so that, with the housing, the inductive winding changes from being the through-hole electronic device to being the converted surface-mount electronic device. As an example, the housing is made of polyoxybenzylmethylenglycolanhydride.

For example, some or all components of various embodiments of the present disclosure each are, individually and/or in combination with at least another component, implemented using one or more software components, one or more hardware components, and/or one or more combinations of software and hardware components. As an example, some or all components of various embodiments of the present disclosure each are, individually and/or in combination with at least another component, implemented in one or more circuits, such as one or more analog circuits and/or one or more digital circuits. For example, various embodiments and/or examples of the present disclosure can be combined.

Although specific embodiments of the present disclosure have been described, it will be understood by those of skill in the art that there are other embodiments that are equivalent to the described embodiments. Accordingly, it is to be understood that the invention is not to be limited by the specific illustrated embodiments.

What is claimed is:

1. A printed circuit board assembly, the printed circuit board assembly comprising:
an aluminum substrate;
an insulating layer on the aluminum substrate;
a conductive layer on the insulating layer; and
one or more surface-mount electronic devices on the aluminum substrate through the conductive layer and the insulating layer;
wherein:
the one or more surface-mount electronic devices include at least one converted surface-mount electronic device, the one converted surface-mount electronic device being converted from a through-hole electronic device; and
the one converted surface-mount electronic device is on the aluminum substrate through the conductive layer and the insulating layer;
wherein the aluminum substrate is made of aluminum.

2. The printed circuit board assembly of claim 1 wherein:
the aluminum substrate includes a first surface and a second surface;
the insulating layer includes a third surface and a fourth surface; and
the conductive layer includes a fifth surface and a sixth surface;
wherein:
the second surface of the aluminum substrate is in direct or indirect contact with the third surface of the insulating layer; and
the fourth surface of the insulating layer is in direct or indirect contact with the fifth surface of the conductive layer.

3. The printed circuit board assembly of claim 2 wherein the one converted surface-mount electronic device is on the sixth surface of the conductive layer.

4. The printed circuit board assembly of claim 1 does not include any through-hole electronic device.

5. The printed circuit board assembly of claim 1, and further comprising one or more through-hole electronic devices.

6. The printed circuit board assembly of claim 1 wherein the one converted surface-mount electronic device is not a power electronic device.

7. The printed circuit board assembly of claim 1 wherein:
the one converted surface-mount electronic device is a power electronic device; and
the power electronic device is not in direct contact with any heat sink.

8. The printed circuit board assembly of claim 1 does not include any heat sink.

9. The printed circuit board assembly of claim 1, and further comprising a heat sink.

10. The printed circuit board assembly of claim 9 wherein the heat sink is not in direct contact with any of the one or more surface-mount electronic devices.

11. The printed circuit board assembly of claim 9 wherein:
the one converted surface-mount electronic device is a power electronic device; and
the power electronic device is in contact with the heat sink.

12. The printed circuit board assembly of claim 9 wherein:
the aluminum substrate includes a first surface and a second surface;
the insulating layer includes a third surface and a fourth surface; and
the conductive layer includes a fifth surface and a sixth surface;
wherein:
the second surface of the aluminum substrate is in direct or indirect contact with the third surface of the insulating layer; and
the fourth surface of the insulating layer is in direct or indirect contact with the fifth surface of the conductive layer.

13. The printed circuit board assembly of claim 12 wherein the heat sink is attached to the second surface of the aluminum substrate through the conductive layer and the insulating layer.

14. The printed circuit board assembly of claim 12 wherein the heat sink is attached to the first surface of the aluminum substrate.

15. The printed circuit board assembly of claim 1 wherein the one converted surface-mount electronic device is an insulated-gate bipolar transistor that has been converted from being a through-hole electronic device.

16. The printed circuit board assembly of claim 1 wherein the one converted surface-mount electronic device is an inductive winding that has been converted from being a through-hole electronic device.

17. A printed circuit board assembly of a home appliance, the printed circuit board assembly comprising:
an aluminum substrate including a first substrate surface and a second substrate surface, the first substrate surface and the second substrate surface being opposite to each other;
one or more converted surface-mount electronic devices on the first substrate surface of the aluminum substrate, the one or more converted surface-mount electronic devices being converted from one or more first through-hole electronic devices; and
one or more additional surface-mount electronic devices on the first substrate surface of the aluminum substrate;
wherein the aluminum substrate is made of aluminum.

18. The printed circuit board assembly of claim 17 does not include any through-hole electronic device.

19. The printed circuit board assembly of claim 17, and further comprising:
one or more second through-hole electronic devices.

20. The printed circuit board assembly of claim 17 wherein:
the one or more converted surface-mount electronic devices include one or more power electronic devices; and
the one or more power electronic devices are not in direct contact with any heat sink.

21. The printed circuit board assembly of claim 17 does not include any heat sink.

22. The printed circuit board assembly of claim 17, and further comprising one or more heat sinks.

23. The printed circuit board assembly of claim 22 wherein the one or more heat sinks are not in direct contact with any of the one or more converted surface-mount electronic devices and are not in direct contact with any of the one or more additional surface-mount electronic devices.

24. The printed circuit board assembly of claim 22 wherein the one or more heat sinks are located on the first substrate surface of the aluminum substrate.

25. The printed circuit board assembly of claim 22 wherein the one or more heat sinks are attached to the second substrate surface of the aluminum substrate.

26. The printed circuit board assembly of claim 25 wherein the one or more heat sinks are in direct contact with the second substrate surface of the aluminum substrate.

27. The printed circuit board assembly of claim 17 wherein:
the one or more converted surface-mount electronic devices include one or more power electronic devices; and
one or more devices of the one or more power electronic devices are in contact with one or more heat sinks.

28. The printed circuit board assembly of claim 17 wherein the one or more converted surface-mount electronic devices include an insulated-gate bipolar transistor that has been converted from being a through-hole electronic device to being a converted surface-mount electronic device.

29. The printed circuit board assembly of claim 17 wherein the one or more converted surface-mount electronic devices include an inductive winding that has been converted from being a through-hole electronic device to being a converted surface-mount electronic device.

30. The printed circuit board assembly of claim 17 wherein the home appliance is an induction cooker.

31. The printed circuit board assembly of claim 17 wherein the home appliance is an electric water heater.

32. An induction cooker comprising:
a printed circuit board assembly;
wherein the printed circuit board assembly includes:
an aluminum substrate;
an insulating layer on the aluminum substrate;
a conductive layer on the insulating layer; and
one or more surface-mount electronic devices on the aluminum substrate through the conductive layer and the insulating layer;
wherein:
the one or more surface-mount electronic devices include at least one converted surface-mount electronic device, the one converted surface-mount electronic device being converted from a through-hole electronic device; and
the one converted surface-mount electronic device is on the aluminum substrate through the conductive layer and the insulating layer;
wherein the aluminum substrate is made of aluminum.

33. The induction cooker of claim 32 wherein:
the aluminum substrate includes a first surface and a second surface;
the insulating layer includes a third surface and a fourth surface; and
the conductive layer includes a fifth surface and a sixth surface;
wherein:
the second surface of the aluminum substrate is in direct or indirect contact with the third surface of the insulating layer; and
the fourth surface of the insulating layer is in direct or indirect contact with the fifth surface of the conductive layer.

34. The induction cooker of claim 33 wherein the one converted surface-mount electronic device is on the sixth surface of the conductive layer.

35. The induction cooker of claim 32 wherein the printed circuit board assembly does not include any through-hole electronic device.

36. The induction cooker of claim 32 wherein the printed circuit board assembly further includes one or more through-hole electronic devices.

37. The induction cooker of claim 32 wherein the one converted surface-mount electronic device is not a power electronic device.

38. The induction cooker of claim 32 wherein:
the one converted surface-mount electronic device is a power electronic device; and
the power electronic device is not in direct contact with any heat sink.

39. The induction cooker of claim 32 wherein the printed circuit board assembly does not include any heat sink.

40. The induction cooker of claim 32 wherein the printed circuit board assembly further includes a heat sink.

41. The induction cooker of claim 40 wherein the heat sink is not in direct contact with any of the one or more surface-mount electronic devices.

42. The induction cooker of claim 40 wherein:
the one converted surface-mount electronic device is a power electronic device; and
the power electronic device is in contact with the heat sink.

43. The induction cooker of claim 40 wherein:
the aluminum substrate includes a first surface and a second surface;
the insulating layer includes a third surface and a fourth surface; and
the conductive layer includes a fifth surface and a sixth surface;
wherein:
the second surface of the aluminum substrate is in direct or indirect contact with the third surface of the insulating layer; and
the fourth surface of the insulating layer is in direct or indirect contact with the fifth surface of the conductive layer.

44. The induction cooker of claim 43 wherein the heat sink is attached to the second surface of the aluminum substrate through the conductive layer and the insulating layer.

45. The induction cooker of claim 43 wherein the heat sink is attached to the first surface of the aluminum substrate.

46. The induction cooker of claim 32 wherein the one converted surface-mount electronic device is an insulated-gate bipolar transistor that has been converted from being a through-hole electronic device.

47. The induction cooker of claim 32 wherein the one converted surface-mount electronic device is an inductive winding that has been converted from being a through-hole electronic device.

48. An induction cooker comprising:
a printed circuit board assembly;
wherein the printed circuit board assembly includes:
an aluminum substrate including a first substrate surface and a second substrate surface, the first substrate surface and the second substrate surface being opposite to each other;
one or more converted surface-mount electronic devices on the first substrate surface of the aluminum substrate, the one or more converted surface-mount electronic devices being converted from one or more first through-hole electronic devices; and
one or more additional surface-mount electronic devices on the first substrate surface of the aluminum substrate;
wherein the aluminum substrate is made of aluminum.

49. The induction cooker of claim 48 wherein the printed circuit board assembly does not include any through-hole electronic device.

50. The induction cooker of claim 48 wherein the printed circuit board assembly further includes one or more second through-hole electronic devices.

51. The induction cooker of claim 48 wherein:
the one or more converted surface-mount electronic devices include one or more power electronic devices; and
the one or more power electronic devices are not in direct contact with any heat sink.

52. The induction cooker of claim 48 wherein the printed circuit board assembly does not include any heat sink.

53. The induction cooker of claim 48 wherein the printed circuit board assembly further includes one or more heat sinks.

54. The induction cooker of claim 53 wherein the one or more heat sinks are not in direct contact with any of the one or more converted surface-mount electronic devices and are not in direct contact with any of the one or more additional surface-mount electronic devices.

55. The induction cooker of claim 53 wherein the one or more heat sinks are located on the first substrate surface of the aluminum substrate.

56. The induction cooker of claim 53 wherein the one or more heat sinks are attached to the second substrate surface of the aluminum substrate.

57. The induction cooker of claim 56 wherein the one or more heat sinks are in direct contact with the second substrate surface of the aluminum substrate.

58. The induction cooker of claim 48 wherein:
the one or more converted surface-mount electronic devices include one or more power electronic devices; and
one or more devices of the one or more power electronic devices are in contact with one or more heat sinks.

59. The induction cooker of claim 48 wherein the one or more converted surface-mount electronic devices include an insulated-gate bipolar transistor that has been converted from being a through-hole electronic device to being a converted surface-mount electronic device.

60. The induction cooker of claim 48 wherein the one or more converted surface-mount electronic devices include an inductive winding that has been converted from being a through-hole electronic device to being a converted surface-mount electronic device.

61. A method for making a printed circuit board assembly (PCBA) of a home appliance, the method comprising:
changing one or more through-hole electronic devices to one or more converted surface-mount electronic devices;
placing the one or more converted surface-mount electronic devices and one or more additional surface-mount electronic devices onto an aluminum PCB substrate by one or more machines with surface mount technology; and
performing reflow soldering to the one or more converted surface-mount electronic devices and the one or more additional surface-mount electronic devices;
wherein the aluminum PCB substrate is made of aluminum.

62. The method of claim 61 wherein the changing one or more through-hole electronic devices to one or more converted surface-mount electronic devices includes:
changing an insulated-gate bipolar transistor from being a through-hole electronic device to being a converted surface-mount electronic device;
wherein the insulated-gate bipolar transistor includes one or more pins.

63. The method of claim 62 wherein the changing an insulated-gate bipolar transistor from being a through-hole electronic device to being a converted surface-mount electronic device includes:
bending the one or more pins of the insulated-gate bipolar transistor so that the insulated-gate bipolar transistor changes from being the through-hole electronic device to being the converted surface-mount electronic device.

64. The method of claim 63 wherein the changing an insulated-gate bipolar transistor from being a through-hole electronic device to being a converted surface-mount electronic device further includes:
placing the insulated-gate bipolar transistor into a package that is larger than the insulated-gate bipolar transistor itself.

65. The method of claim 62 wherein the placing the one or more converted surface-mount electronic devices and one or more additional surface-mount electronic devices onto an aluminum PCB substrate by one or more machines with surface mount technology includes:
placing the insulated-gate bipolar transistor as the converted surface-mount electronic device on an edge region of the aluminum PCB substrate.

66. The method of claim 61 wherein the changing one or more through-hole electronic devices to one or more converted surface-mount electronic devices includes:
changing an inductive winding from being a through-hole electronic device to being a converted surface-mount electronic device;
wherein the inductive winding includes a first pin and a second pin.

67. The method of claim 66 wherein the changing an inductive winding from being a through-hole electronic device to being a converted surface-mount electronic device includes:
placing the inductive winding inside a housing; and
bending the first pin and the second pin so that, with the housing, the inductive winding changes from being the through-hole electronic device to being the converted surface-mount electronic device.

68. The method of claim 67 wherein the housing is made of polyoxybenzylmethylenglycolanhydride.
